(19) United States
(12) Patent Application Publication
(10) Pub. No.: US 2008/0290363 A1
(43) Pub. Date: Nov. 27, 2008

(54) LIGHT EMITTING DIODE PACKAGE

(75) Inventors: Shun-Tian Lin, Taipei (TW); Jyun-Wei Huang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: ADVANCED CONNECTEK INC., Taipei (TW); TYSUN INC., Taipei County (TW)

(21) Appl. No.: 12/056,290

(22) Filed: Mar. 27, 2008

(30) Foreign Application Priority Data
May 23, 2007 (TW) 96118291

(51) Int. Cl. H01L 33/00

(52) U.S. Cl. 257/99; 257/E33.075; 257/E33.059

(57) ABSTRACT

A light emitting diode (LED) package including a heat dissipation base, an electrical insulating layer, a circuit layer, and an LED chip is provided. The electrical insulating layer is disposed on the heat dissipation base. The circuit layer is disposed on the electrical insulating layer. The circuit layer has a receiving hole extending and passing through the electrical insulating layer for exposing a portion of the heat dissipation base. The LED chip is disposed on the heat dissipation base exposed by the receiving hole and is electrically connected to the circuit layer.

### CROSS-REFERENCE TO RELATED APPLICATION

This application claims the priority benefit of Taiwan application serial no. 96118291, filed on May 23, 2007. The entirety the above-mentioned patent application is hereby incorporated by reference herein and made a part of specification.

### BACKGROUND OF THE INVENTION

1. Field of the Invention

The present invention generally relates to a light emitting diode (LED) package, in particular, to an LED package with a two-phase flow heat-conducting medium as a heat dissipation base.

2. Description of Related Art

As the luminous efficiency of light emitting diodes (LEDs) is increasingly improved, LEDs have replaced fluorescent lamps and incandescent lamps in some fields, for example, lamp sources of scanners requiring for quick response, backlight sources or front light sources of liquid crystal displays (LCDs), illumination for dashboards of automobiles, traffic lights, and common illumination devices. Compared with conventional lamps, the LEDs have absolute advantages, for example, small volume, long lifespan, low driving voltage/current, non-fragile, mercury free (no pollution), and good luminous efficiency (power saving). However, with the improvement of the luminous efficiency of LEDs, heat dissipation efficiency has become the major factor that influences the reliability of the LEDs.

FIG. 1 is a cross-sectional view of a conventional LED module. Referring to FIG. 1, in the conventional LED module 100, a pin 112 of an LED package 110 is first welded on a printed circuit board (PCB) 120, such that the operating voltage is transmitted to the LED package 110 through the PCB 120. However, with the increasing improvement of the luminous efficiency of the LED package 110, heat generated during the light-emitting process is increased sharply. In order to avoid the overheating to damage the LED package 110, the PCB 120 is disposed on a heat dissipation base 130, so as to quickly conduct the heat to the outside through the heat dissipation base 130, thereby improve the heat dissipation efficiency. However, the heat generated by the LED package 110 is transmitted to the heat dissipation base 130 through the PCB 120. Since the heat conductivity of the PCB 120 is poor and is basically considered to be a heat barrier layer, a large amount of heat energy is accumulated in the PCB 120 and cannot be effectively conducted to the heat dissipation base 130, and thus the overall heat dissipation effect is severely affected and the service lifespan is shortened. Further, in order to place the LED package 110 at the optimal position to improve the luminous efficiency, the PCB 120 must be first fixed at a correct position on the heat dissipation base 130, which leads to more hours and costs of assembly.

Therefore, it is actually a major problem in need of solution how to improve the current package mode of LEDs to achieve better heat dissipation efficiency and longer service life.

### SUMMARY OF THE INVENTION

Accordingly, the present invention is directed to an LED package for solving the problem of poor heat dissipation efficiency in prior art caused by the LED directly fixed on a printed circuit board (PCB).

The present invention provides an LED package, which includes a heat dissipation base, an electrical insulating layer, a circuit layer, and an LED chip. The electrical insulating layer is disposed on the heat dissipation base. The circuit layer is disposed on the electrical insulating layer. The circuit layer has a receiving hole extending and passing through the electrical insulating layer for exposing a portion of the heat dissipation base. The LED chip is disposed on the heat dissipation base exposed by the receiving hole and is electrically connected to the circuit layer.

In an embodiment of the present invention, the heat dissipation base includes a heat pipe, a heat column, or a vapor chamber.

In an embodiment of the present invention, the LED package further includes a plurality of cooling fins disposed at the bottom of the heat dissipation base.

In an embodiment of the present invention, the electrical insulating layer and the circuit layer are comprised of an electrical insulating layer and a circuit layer of a printed circuit board (PCB).

In an embodiment of the present invention, the electrical insulating layer is comprised of a polymer organic material, and the circuit layer is comprised of a metal coating layer, a metal sintered layer, or a metal foil.

In an embodiment of the present invention, the electrical insulating layer is comprised of a ceramic material, and the circuit layer is comprised of a metal coating layer, a metal sintered layer, or a metal foil.

In an embodiment of the present invention, the electrical insulating layer is comprised of a composite material of a polymer organic and a ceramic powder, and the circuit layer is comprised of a metal coating layer, a metal sintered layer, or a metal foil.

In an embodiment of the present invention, the LED package further includes an adhesive layer, and the LED chip is fixed on the heat dissipation base by the adhesive layer.

In an embodiment of the present invention, the LED package further includes a plurality of bonding wires connected between the LED chip and the circuit layer.

In an embodiment of the present invention, the LED package further includes a molding compound disposed on the heat dissipation base and encapsulating the LED chip and the bonding wires.

The LED package of the present invention directly disposes an LED chip on the heat dissipation base with a two-phase flow as the heat-conducting medium, for example, a heat pipe, a heat column, or a vapor chamber. Thus, the heat energy generated during the operation of the LED chip can be directly dissipated from the bottom of the heat dissipation base, so as to effectively solve the heat dissipation problem in the current LED packaging. Further, a plurality of cooling fins may be optionally disposed at the bottom of the heat dissipation base, so as to further improve the heat dissipation effect of the heat dissipation base.

In order to make the features and advantages of the present invention clearer and more understandable, the following embodiments are illustrated in detail with reference to the appended drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional LED module.

FIG. 2 is a schematic cross-sectional view of an LED package according to an embodiment of the present invention.

FIG. 3 is a schematic cross-sectional view of an LED package according to another embodiment of the present invention.

FIG. 4 is a schematic cross-sectional view of an LED package according to another embodiment of the present invention.

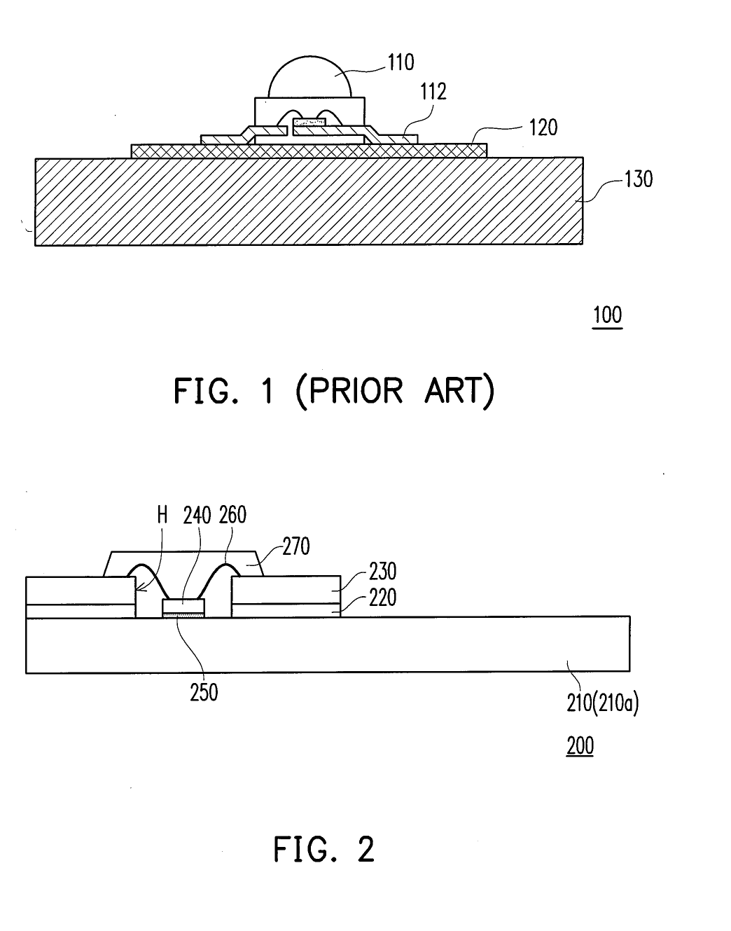

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

FIG. 2 is a schematic cross-sectional view of an LED package according to an embodiment of the present invention. Referring to FIG. 2, an LED package 200 mainly includes a heat dissipation base 210, an electrical insulating layer 220, a circuit layer 230, and an LED chip 240. The LED package 200 mainly utilizes a heat dissipation device (for example, a heat pipe, a heat column, or a vapor chamber) with a two-phase flow as the heat-conducting medium. Thus, the heat energy generated by the LED chip is directly removed by the heat dissipation device, thereby improving the heat dissipation efficiency of the package. Hereinafter, the elements and the connection relationships thereof of the LED package 200 are illustrated with reference to the drawings.

The heat dissipation base 210 carries the LED chip 240. The present invention mainly utilizes a high heat-conducting device with two-phase flow as the heat-conducting medium, such as a heat pipe, a heat column, or a vapor chamber, so as to carry the LED chip 240. Thus, the heat energy generated by the LED chip 240 during operation can be directly carried away by the heat dissipation base 210, thereby improving the heat dissipation efficiency. In this embodiment, the heat dissipation base 210 is, for example, a flat heat pipe 210a.

The electrical insulating layer 220 is disposed on the heat dissipation base 210. The circuit layer 230 is disposed on the electrical insulating layer 220. The circuit layer 230 has a receiving hole H extending and passing through the electrical insulating layer 220 for exposing a portion of the heat dissipation base 210. In an embodiment of the present invention, the electrical insulating layer 220 and the circuit layer 230 are comprised of an insulting layer and a circuit layer of a PCB. Further, the electrical insulating layer 220 may also be comprised of a polymer organic material or a ceramic material, and the circuit layer 230 may be comprised of a metal coating layer, a metal sintered layer, or a metal foil. The materials of the electrical insulating layer 220 and the circuit layer 230 are not limited in the present invention.

The LED chip 240 is disposed on the heat dissipation base 210 exposed by the receiving hole H and is electrically connected to the circuit layer 230. In this embodiment, the LED package 200 further includes an adhesive layer 250, such that the LED chip 240 is fixed on the heat dissipation base 210 by the adhesive layer 250. However, in the present invention, the LED chip 240 may also be fixed on the heat dissipation base 210 by other means, which should not be limited thereby. Further, a plurality of bonding wires 260 may be formed between the LED chip 240 and the circuit layer 230 by a wire bonding technique, so as to electrically connect the LED chip 240 and the circuit layer 230. Further, in order to prevent damaging and humidity getting into the LED chip 240 and the bonding wires 260, a molding compound 270 may be optionally applied on the heat dissipation base 210. The molding compound 270 encapsulates the circuit layer 230 and covers the receiving hole H, particularly the LED chip 240 and the bonding wires 260, so as to prevent damaging and humidity getting therein.

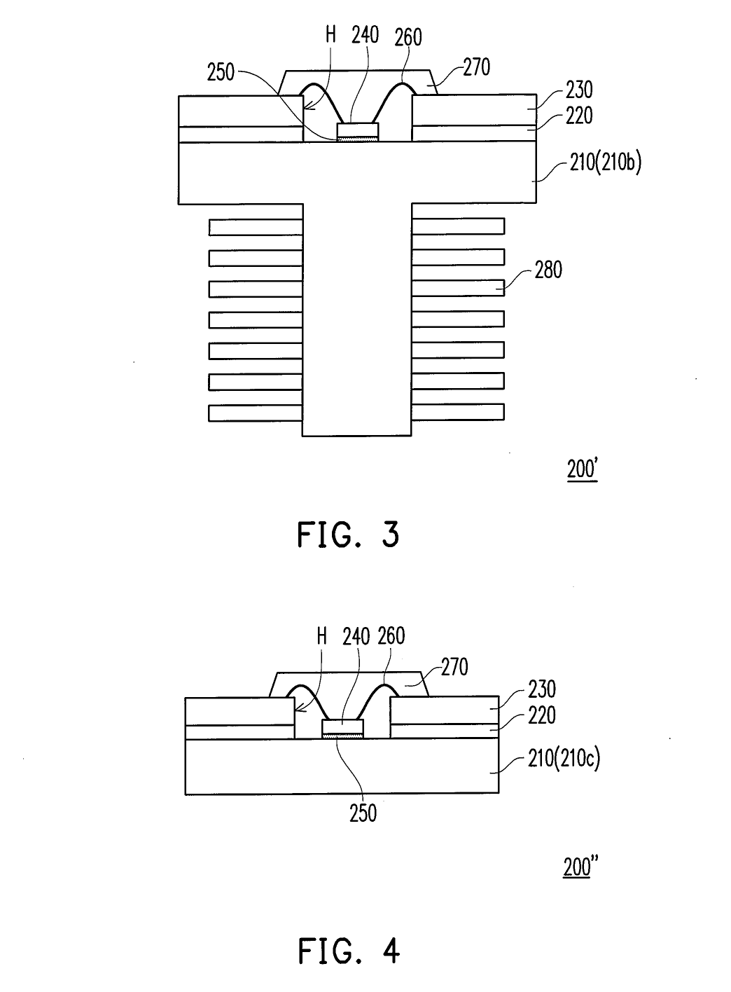

FIG. 3 is a schematic cross-sectional view of an LED package according to another embodiment of the present invention. Referring to FIG. 3, an LED package 200′ is substantially the same as the LED package 200 in FIG. 2, and only the difference therebetween is described as follows. The LED package 200′ utilizes a heat column 210b as the heat dissipation base 210, and the LED chip 240 is also directly fixed on the heat column 210b, so as to achieve good heat dissipation effect. Further, several cooling fins 280 may also be bonded at the bottom of the heat dissipation base 210 to increase heat dissipation area.

FIG. 4 is a schematic cross-sectional view of an LED package according to another embodiment of the present invention. Referring to FIG. 4, an LED package 200″ is substantially the same as the LED package 200 in FIG. 2, and only the difference therebetween is described as follows. The LED package 200″ utilizes a vapor chamber 210c as the heat dissipation base 210, and the LED chip 240 is directly fixed on the heat column 210c, so as to achieve good heat dissipation effect.

In view of the above, the LED package of the present invention mainly includes directly disposing the LED chip on the heat dissipation base with a two-phase flow as the heat-conducting medium, for example, a heat pipe, a heat column, or a vapor chamber, such that the heat energy generated by the LED chip during operation can be directly discharged from the bottom of the heat dissipation base, so as to effectively solve the heat dissipation problem in the current LED packaging. Further, a plurality of cooling fins may be optionally disposed at the bottom of the heat dissipation base, so as to further improve the heat dissipation effect of the heat dissipation base.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode (LED) package, comprising:
a heat dissipation base;
an electrical insulating layer, disposed on the heat dissipation base;
a circuit layer, disposed on the electrical insulating layer, and formed with a receiving hole extending and passing through the electrical insulating layer for exposing a portion of the heat dissipation base; and
an LED chip, disposed on the heat dissipation base exposed by the receiving hole, and electrically connected to the circuit layer.

2. The LED package according to claim 1, wherein the heat dissipation base comprises a heat pipe, a heat column, or a vapor chamber.

3. The LED package according to claim 1, further comprising a plurality of cooling fins disposed at a bottom of the heat dissipation base.

4. The LED package according to claim 1, wherein the electrical insulating layer and the circuit layer are comprised of an insulating layer and a circuit layer of a printed circuit board (PCB).

5. The LED package according to claim 1, wherein the electrical insulating layer is comprised of a polymer organic material, and the circuit layer is comprised of a metal coating layer, a metal sintered layer, or a metal foil.

6. The LED package according to claim 1, wherein the electrical insulating layer is comprised of a ceramic material, and the circuit layer is comprised of a metal coating layer, a metal sintered layer, or a metal foil.

7. The LED package according to claim 1, wherein the electrical insulating layer is comprised of a composite material composed of polymer organic material and a ceramic powder, and the circuit layer is comprised of a metal coating layer, a metal sintered layer, or a metal foil.

8. The LED package according to claim 1, further comprising an adhesive layer, wherein the LED chip is fixed on the heat dissipation base by the adhesive layer.

9. The LED package according to claim 1, further comprising a plurality of bonding wires connected between the LED chip and the circuit layer.

10. The LED package according to claim 1, further comprising a molding compound applied on the circuit layer and covering the receiving hole.
